(19) United States
(12) Patent Application Publication
(10) Pub. No.: US 2010/0127341 A1
(43) Pub. Date: May 27, 2010

(54) Imaging Device Manufacturing Method, Imaging Device and Portable Terminal

(75) Inventors: Keiichi Kawazu, Kanagawa (JP); Seiichi Isoguchi, Tokyo (JP)

Correspondence Address: COHEN, PONTANI, LIEBERMAN & PAVANE LLP, 551 FIFTH AVENUE, SUITE 1210, NEW YORK, NY, 10176, US

(73) Assignee: KONICA MINOLTA OPTO, INC., Hachioji-shi, Tokyo (JP)

(21) Appl. No.: 12/595,927

(22) PCT Filed: Apr. 7, 2008
(86) PCT No.: PCT/JP2008/056887

§ 371 Date: Oct. 14, 2009

(30) Foreign Application Priority Data
Apr. 17, 2007 (JP) 2007-108069

(51) Int. Cl. H01L 31/0232; H01L 31/18

(52) U.S. Cl. 257/432; 438/65; 257/E31.127; 257/E31.117

(57) ABSTRACT

Provided are a method for manufacturing a low cost imaging device, the low cost imaging device manufactured by such method and a portable terminal using the imaging device. A silicon wafer 11 is cut into imaging elements 12, and a plurality of the imaging elements 12 are placed on a substrate 21. Thus only non-defective imaging elements 12 are sent to a subsequent process. By discriminating a defective imaging element 12 prior to cutting, an imaging optical unit OU is saved from being combined with the defective product whereby the imaging device can be manufactured at a low cost.

### TECHNICAL FIELD

The present invention relates to a manufacturing method of a compact imaging device suitable for being installed in, for example, a mobile phone, an imaging device and a portable terminal.

### BACKGROUND

In recent years, a compact and thin imaging device is increasingly installed in a portable terminal representing a compact and thin electronic instrument such as a mobile phone and a PDA (Personal Digital Assistant). Utilizing these instruments, besides phonetical information, image information can be transmitted between remote places.

As a manufacturing method of such a compact imaging device, there is known a method wherein a plurality of image sensors are formed in a shape of an array on a silicon wafer, then a lens array wherein a plurality of optical lenses are formed is bonded with the silicon wafer, and the wafer is cut in accordance with arrangement of the image sensors (for example, refer to Patent Document 1: Unexamined Japanese Patent Application Publication No, 2002-290842.

Patent Document 1: Unexamined Japanese Patent Application Publication No. 2002-290842.

### DISCLOSURE OF THE INVENTION

### Problems to be Resolve by the Invention

In the manufacturing method of the aforesaid Patent Document 1, since the wafer is cut to separate after bonding a plurality of the lens arrays corresponding to individual image sensors on the silicon wafer, it is unavoidable that the lenses are disposed on defective image sensors having some kinds of problems. Therefore the lens along with the defective image sensor has to be discarded, which results in increase of the cost.

The present invention has one aspect to solve the above problem and an object of the present invention is to provide a manufacturing method which enables lower cost manufacturing of the imaging device, a lower cost imaging device through the manufacturing method thereof and a portable terminal using the imaging device thereof.

### Means to Resolve the Problems

A manufacturing method of an imaging device described in claim 1 having an imaging optical unit to lead object light and an imaging element on which a plurality of light receiving pixel sections are formed to conduct photoelectric conversion of the object light led by the imaging optical unit includes steps of:

forming a plurality of the imaging elements on one surface of an silicon wafer;

disposing at least a portion of the imaging optical unit to face the light receiving pixels of non-defective imaging elements respectively;

cutting the silicon wafer into each imaging element;

placing a plurality of the imaging elements having been cut along with at least the portion of the imaging optical unit;

connecting the substrate with the plurality of the imaging elements electrically;

molding the plurality of the imaging elements sealed by the substrate and at least some of the imaging optical units with a resin integrally; and

separating the molded substrate into each imaging element by cutting.

According to the present invention, by cutting the silicon wafer into each imaging element and placing a plurality of the imaging elements on a substrate, non-defective imaging elements can be put into subsequent processes. In addition, by judging the defective elements before cutting, the imaging optical units to be combined with the imagine elements are saved, thus the imaging device can be manufactured at a low cost.

The imaging device manufacturing method described in claim 2 is based on that described in claim 1 is further characterized in that at least the portion of the imaging optical unit is a lens and a lens frame to retain the lens. For example, in order to passing through a solder reflow bath, a glass lens superior in heat resistance is used in the imaging optical unit. However, since the glass lens has an inferior molding property compared to that of the plastic lens, it is difficult to protrude a flange section in an optical axis direction. Thus the imaging optical unit is formed by installing the glass lens in the lens frame in advance, then the above imaging optical units are respectively disposed so as to face the light receiving pixel section of the imaging element, whereby a distance between the lens and the imaging element can be adjusted accurately.

The imaging device manufacturing method described in claim 3 based on that described in claim 1 is further characterized in that at least a portion of the imaging optical units is a lens frame to retain the lens. After the lens frame is disposed so as to face the light receiving pixel section of the imaging element, by installing the lens, a distance between the lens and the imaging element can be adjusted accurately.

The imaging device manufacturing method described in claim 4 based on that described in any one of claims 1 to 3 is further characterized in that the imaging optical unit is provided with a glass lens.

The imaging device described in claim 5 is an imaging device disposed on a substrate having: an imaging element, having a light receiving surface on which pixels are installed, disposed on the substrate; a lens to from an object image on the light receiving surface of the imaging element; and a lens frame to retain the lens, wherein the imaging element and the lens frame are molded integrally with a resin, thereby being manufactured at a low cost.

The portable terminal described in claim 6 is characterized in that the imaging device described in claim 5 is installed therein.

### Effect of the Invention

According to the present invention, there are provided the manufacturing method capable of manufacturing the lower cost imaging device and the portable terminal using the imaging device thereof.

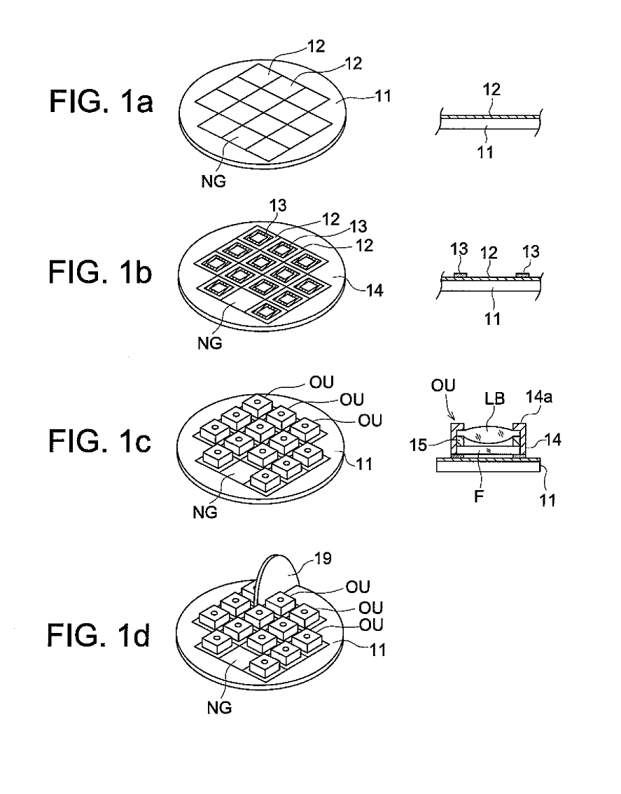

FIG. 1a to 1d are schematic diagrams showing processes of a manufacturing method of an imaging device related to the present embodiment in a preceding period.

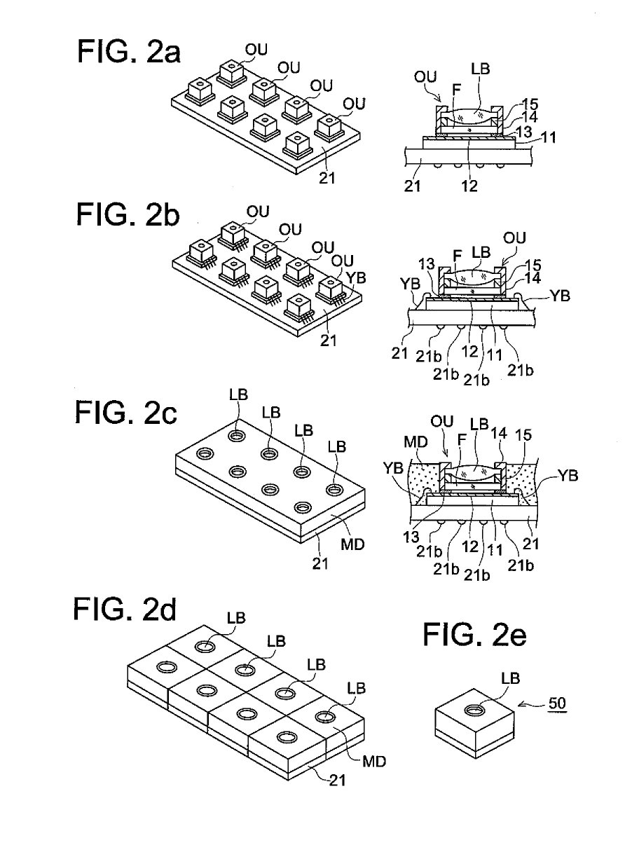

FIGS. 2a to 2d are schematic diagrams showing processes of a manufacturing method of an imaging device related to the present embodiment in a latter period.

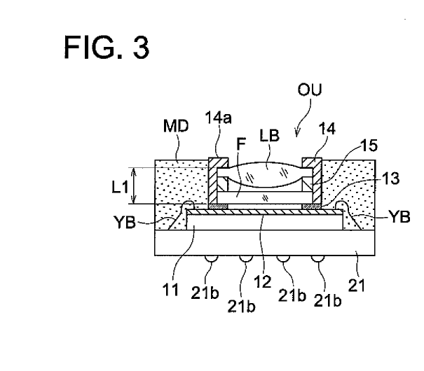

FIG. 3 is a cross-sectional view showing an imaging device manufactured in the above manufacturing processes.

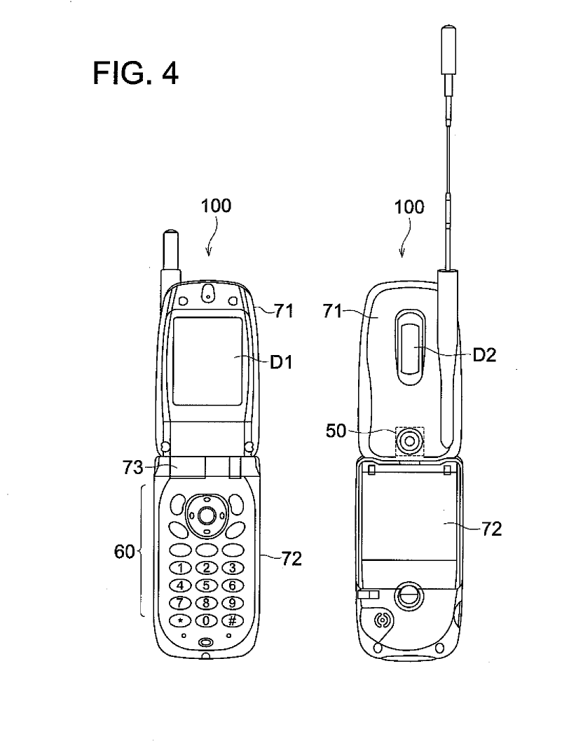

FIG. 4 is an external view of a mobile phone 100 representing an exemplary portable terminal having an imaging device 50.

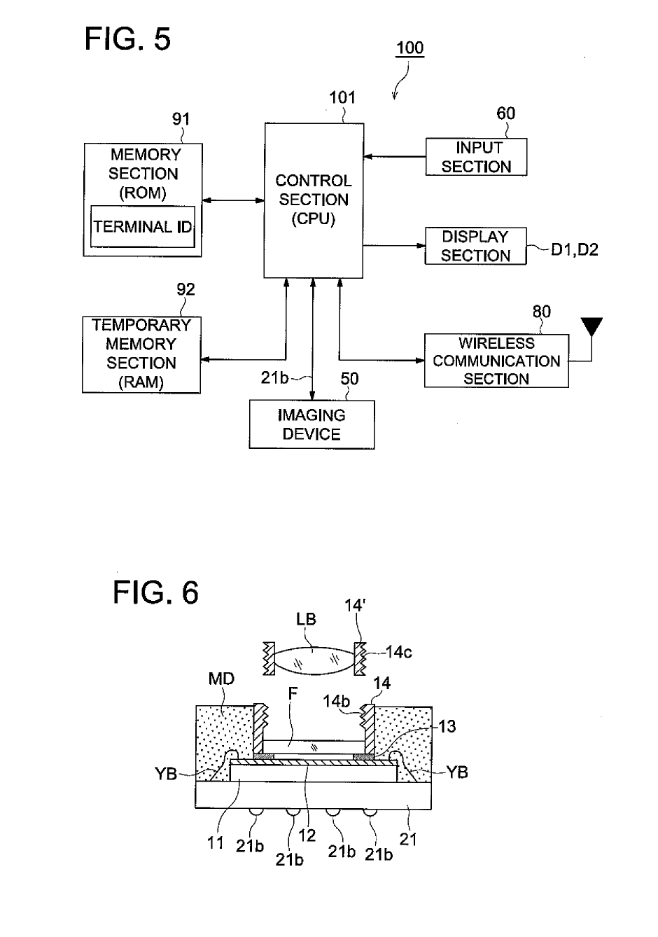

FIG. 5 is a block-diagram of control of a mobile phone 100.

FIG. 6 is a cross-sectional view equivalent to that in FIG. 3 related to an exemplary variation of the present embodiment.

### DESCRIPTION OF THE SYMBOLS

11 silicon wafer

12 imaging element

13 adhesive

14 lens frame

15 spacer

19 dicing blade

21 substrate

21b external electrode

50 imaging device

60 operation button

71 upper housing

72 lower housing

73 hinge

80 wireless communication section

91 memory section

100 mobile phone

101 control section

D1, D2 display screen

F IR cut filter

ID terminal

LB lens

MD resin material

OU imaging optical unit

YB wire bonding

### DESCRIPTION OF THE PREFERRED EMBODIMENTS

An embodiment of the present invention will be described with reference to the drawings. FIG. 1a to 1d are schematic diagrams showing processes of the manufacturing method of the imaging device related to the present embodiment in a preceding period. The left figures show outlined total views of a wafer in each status, and right figures are outlined cross-sectional views of a single imaging element in the wafer.

First, a plurality of imaging elements 12 are formed on one surface of the silicon wafer 11 shown by FIG. 1a. More specifically, By repeating known film forming processes such as a photo lithography process, an etching process and an impurity addition process, a transition electrode, an isolation film, and wiring are formed in a multilayer structure, and the plurality of the imaging elements 12 are formed in a shape of an array. The above imaging elements 12 are, for example, CCD (Charge Coupled Device) type image sensors, and CMOS (Complementary Metal-Oxide Semiconductor) type image sensors.

Alongside the above, the imaging optical unit OU is assembled. As the cross-sectional view in FIG. 1c shows, the imaging optical unit OU is configured with a lens frame 14 in a shape of a rectangular tubular, an IR cut filter F disposed under the lens frame 14, a glass lens LB disposed above the lens frame 14 and a spacer 15 disposed between IR cut filter F and the lens LB, which are bonded each other.

Further, chips of image elements 12 on the silicon wafer 11 are examined to distinguish defectives from non-defectives (NG in FIG. 1a to 1d are defectives). Next, as FIG. 1b shows, an adhesive 13 is applied onto only vicinities of all the imaging elements 12 which have been judged to be non-defectives. The adhesive 13 is applied onto a position except a light receiving pixel area of the imaging element 12. Also, by adjusting application amount of the adhesive, a distance between the imaging optical unit OU (for example, the lens LB) which is bonded above the light receiving pixel area of the imaging element 12 and the imaging element 12 is determined.

Incidentally, distinguishing of the chips of the imaging element 12, i.e. non-defectives from defectives is carried out using semiconductor examination apparatus commercially available. The chip is judged as a non-defective if defects are not found. The followings are confirmed as examination items; chipping of wiring patterns, existence of burrs at time of dicing, a width and a pitch of the wiring pattern, existence of flaws, taint and crack, and adhesion of foreign matters.

After that, as FIG. 1c shows, the imaging optical unit OU is placed on the adhesive applied so as to be bonded. By bonding the imaging optical unit OU, the light receiving pixel area of the imaging element 12 is sealed by the lens frame 14 and the IR cut filter F.

Next, as FIG. 1d shows, the silicon wafer 11 is cut into individual imaging elements by a dicing saw 19. Whereby, individual chips of the imaging elements 12, wherein the light receiving pixel area is sealed by the image optical unit OU, are formed.

Thus, since only non-defective imaging elements 12 are combined with the imaging optical units, the imaging optical unit OU is not wasted and a yield rate can be enhanced.

FIGS. 2a to 2d are schematic diagrams showing processes of the manufacturing method of an imaging device related to the present embodiment in a later process. A plurality of the chips of the imaging element 12, wherein the chips of the imaging elements 12 are bonded respectively with the imaging optical units OU, are lined up and placed on the substrate 21. On the substrate 21, a plurality of wires corresponding to individual chips of the imaging element 12 are formed so that the plurality of the chips of the imaging element 12 can be placed thereon.

Next, as FIG. 2b shows, the chip of the imaging element 12 and the substrate 21 are electrically connected through wire bonging YB. On the other surface of the substrate 21, a plurality of external electrodes 21b (for example, solder ball) used for connecting with other unillustrated control substrates are formed. Whereby, input and output of signals between the other unillustrated control substrates in connection with the substrate 21 and the imaging element 12 are possible.

After that, as FIG. 2c shows, a resin material MD is filled on an imaging element 12 side surface of the substrate 21 so as to cover an outer circumference of the imaging optical unit OU as the figure shows, and the imaging optical unit OU is molded integrally in the way that only the image surface side of the lens LB is exposed.

Further, by cutting and separating the imaging optical unit OU molded integrally, the imaging element 12 and the substrate 21 along the broken lines shown in FIG. 2b, individual imaging devices 50 shown by FIG. 2e are separated and completed.

As described above, in the present example, in the processes of cutting the silicon wafer into the individual chips of the imaging elements and placing the plurality of the chips of the imaging elements on the substrate, only non-defective chips can be used for the latter process, whereby the manufacturing method to manufacture the imaging device at low cost can be obtained.

FIG. 3 is a cross-sectional view showing the imaging device manufactured in the aforesaid manufacturing method. As FIG. 3 shows, the imaging device 50 is provided with the imaging element 12. In FIG. 1, in the imaging element 12, at a center section of a light receiving side plane thereof, a photoelectric conversion section (unillustrated) representing a light receiving pixel section where the pixels (photoelectric conversion elements) are disposed two dimensionally is formed. The photoelectric conversion section performs photoelectric conversion of an object image formed through the lens LB, and at a periphery thereof, a signal processing circuitry section (unillustrated) is formed. The signal processing circuitry section is provided with a drive circuitry section to drive each pixel sequentially and to obtain a signal charge, an A/D conversion section to convert each signal charge into a digital signal and a signal processing section to create an imaging signal output using the digital signal thereof which are not illustrate and are connected with the substrate 21 through the terminal (sensor pad) on the surface via wiring bonding YB so as to communicate signals with an outside.

The imaging element 12 converts the signal charge form the photoelectric conversion section into an image signal and outputs to a prescribed circuitry on the substrate 21. Incidentally, the imaging element is not limited to the CMOS type imaging sensor, thus other imaging elements such as a CCD can be used.

In FIG. 3 an end section of the lens frame 14 in a tubular shape formed with a black resin contacts with a periphery of the imaging element 12, via a resin having a prescribed thickness. At an upper part of inside the lens frame, a glass lens LB is formed which is in contact with an upper surface of the IR cut filter F via a spacer 15 having a prescribed thickness. The lens LB is in contact with a lower surface of an upper flange section 14a of the lens frame 14. Here, by adjusting a length L1 (a length of the leg section of the lens frame 14) from the lower surface of the upper flange section 14a to a bottom end of the lens frame 14, the lens LB and the imaging element 12 can be positioned in an optical axis direction within the prescribed range, thus focusing work can be simplified. Incidentally, the prescribed range means the range of about ±F×2P (F: lens F number, P: pixel pitch of imaging element) in an air equivalent length, within which a deviation between the light receiving surface of the imaging element 12 and an imaging point of the lens LB falls.

A portable terminal provided with the imaging device 50 manufactured as above will be described. FIG. 4 is an external view of a mobile phone 100 representing an example of a portable terminal provided with the imaging device 50.

The mobile phone 100 shown by FIG. 4 has an upper housing 71 as a case provided with display screens D1 and D2 and a lower housing 72 provided with operation buttons 60 representing an input section which are connected via a hinge 73. The imaging device 50 is installed blow the display screen D2 in the upper housing 71 so that the imaging device 50 can capture light from an outer surface side of the upper housing 71.

Meanwhile, the position of the imaging device can be above the display screen D2 or at a side surface in the upper housing 71. The mobile phone is not limited to a folding type.

FIG. 5 is a control block diagram of the mobile phone 100. As FIG. 5 shows, the imaging device 50 is connected to the control section 101 of the mobile phone 100 via the external electrode 21b so as to output image signals such as a brightness signal and a color difference signal to the control section 101.

On the other hand, the mobile phone 100 to perform overall control for each section is provided with a control section (CPU) 101 to execute a program in accordance with each process, the operation buttons 60 representing the input section to input instructions such as telephone numbers, display screens D1 and D2 to display prescribed data and photographed images, a wireless communication section 80 to realize various data communication between an external server, a memory section (ROM) 91 to store various necessary data such as a system program for the mobile phone 100, various processing programs and an ID of the terminal, and a temporally memory section (RAM) 92 to temporarily store various processing programs, processed data to be executed by the control section 101 and image data captured by the imaging device 50 which is used as a work area.

Also, the image signal inputted from the imaging device 50 is stored in the memory section 91 through the control section 101 of the mobile phone 100, and displayed on the display screen D1 or D2, furthermore, transmitted to an outside as image information via the wireless communication section 80.

FIG. 6 is a cross-sectional view which is similar to FIG. 3 related to an exemplary variation of the present embodiment. In FIG. 6, a periphery of the lens frame 14 representing a part of the image optical unit OU is molded with the resin material MD and integrated with the imaging element 12 and the substrate 21. A female thread 14b is formed inside the lens frame 14. On the other hand, on the outer circumference of a holder 14′ in a shape of a cylinder retaining the lens LB, a male thread 14c is formed. By engaging the female thread 14b with the male thread 14c, the lens LB is mounted on the lens frame 14 via the holder 14′. When this occurs, by adjusting the engaging amount of the threads of the holder 14′, the lens LB and the imaging element 12 are position in the light axis direction within the prescribed range.

As above, while the present invention has been described with reference to the embodiments, it is to be understood that changes and variations may be made without departing from the spirit or scope of the appended claims. For example, by bonding only the lens frame 14 onto the silicon wafer 11 in advance, the IR cut filter F and the lens LB can be installed onto the lens frame 14 from an object side after completion of molding. Or, the IR cut filter is no always necessary to be provided. For example, the filter can be omitted by forming an IR cut film on the optical surface of the lens LB.

1. A manufacturing method of an imaging device having an imaging optical unit to lead object light and an imaging element at which a plurality of light receiving pixel sections are formed to conduct photoelectric conversion of the object light led by the imaging optical unit, comprising steps of:
forming a plurality of the imaging elements on one surface of a silicon wafer;
disposing at least a portion of the imaging optical unit so as to face the light receiving pixel sections of non-defective imaging elements respectively;
cutting the silicon wafer into each imaging element;
placing a plurality of the imaging elements having been cut along with at least the portion of the imaging optical unit on a substrate;
connecting the substrate with the plurality of the imaging elements electrically;
molding the plurality of the imaging elements sealed by the substrate and at least the portion of the imaging optical units with a resin integrally; and
separating the molded substrate into each imaging element by cutting.

2. The manufacturing method of the imaging device of claim 1, wherein at least the portion of the imaging optical unit is a lens and a lens frame to retain the lens.

3. The manufacturing method of the imaging device of claim 1, wherein at least the portion of the imaging optical unit is a lens frame to retain the lens.

4. The manufacturing method of the imaging device of any claim 1, wherein the imaging optical unit has a glass lens.

5. An imaging device disposed on a substrate, comprising;
an imaging element, having a light receiving surface on which pixels are installed, disposed on the substrate;
a lens to form an object image on the light receiving surface of the imaging element; and
a lens frame to retain the lens,
wherein the imaging element and the lens frame are molded integrally with a resin.

6. A portable terminal comprising the imaging device of claim 5.
